(19) United States
(12) Patent Application Publication
(10) Pub. No.: US 2026/0161840 A1
(43) Pub. Date: Jun. 11, 2026

(54) DYNAMIC ADAPTATION OF 3D PRINTED MODELS BASED ON PREDICTED STRESS GENERATION DUE TO THERMAL EXPANSION

(71) Applicant: INTERNATIONAL BUSINESS MACHINES CORPORATION, Armonk, NY (US)

(72) Inventors: Carolina GARCIA DELGADO, Zapopan (MX); Sarbajit Kumar RAKSHIT, Kolkata (IN); Jeremy R. FOX, Georgetown, TX (US); Karelly RUELAS IBARRA, San Pedro Tlaquepaque (MX)

(21) Appl. No.: 18/975,200

(22) Filed: Dec. 10, 2024

(51) Int. Cl. G06F 30/17; B29C 64/386; B33Y 50/00

(52) U.S. Cl. CPC G06F 30/17; B29C 64/386; B33Y 50/00

(57) ABSTRACT

A computer-implemented method includes: predicting thermal expansion in an object by analyzing a digital model of the object, wherein the digital model is based on a specification of the object in which the object is composed of a first three-dimensional printing material; predicting stress in the object based on the predicted thermal expansion; identifying a portion of the object based on the predicted thermal expansion or the predicted stress; performing simulations using different digital models of the object that correspond to different designs of the object that include one or more other three-dimensional printing materials at the portion, wherein a respective one of the simulations for a respective one of the different designs predicts thermal expansion and stress associated with the respective one of the different designs; and altering the specification of the object based on the simulations.

### BACKGROUND

Aspects of the present invention relate generally to three-dimensional (3D) printed objects. Objects manufactured using 3D printing may have various shapes and uses, including being used in machines that have moving parts.

### SUMMARY

In a first aspect of the invention, there is a computer-implemented method including: predicting thermal expansion in an object by analyzing a digital model of the object, wherein the digital model is based on a specification of the object in which the object is composed of a first three-dimensional printing material; predicting stress in the object based on the predicted thermal expansion; identifying a portion of the object based on the predicted thermal expansion or the predicted stress; performing simulations using different digital models of the object that correspond to different designs of the object that include one or more other three-dimensional printing materials at the portion, wherein a respective one of the simulations for a respective one of the different designs predicts thermal expansion and stress associated with the respective one of the different designs; and altering the specification of the object based on the simulations.

In another aspect of the invention, there is a computer program product including one or more computer-readable storage media and program instructions stored on the one or more computer-readable storage media to perform operations comprising: predicting thermal expansion in an object by analyzing a digital model of the object using finite element analysis, wherein the digital model is based on a specification of the object in which the object is composed of a first three-dimensional printing material; predicting stress in the object based on the predicted thermal expansion; identifying a portion of the object based on the predicted thermal expansion or the predicted stress; performing simulations using different digital models of the object that correspond to different designs of the object that include one or more other three-dimensional printing materials at the portion, wherein a respective one of the simulations for a respective one of the different designs predicts thermal expansion and stress associated with the respective one of the different designs; and altering the specification of the object based on the simulations.

In another aspect of the invention, there is a system including a processor set, one or more computer-readable storage media, and program instructions stored on the one or more computer-readable storage media to cause the processor set to perform operations comprising: predicting thermal expansion in an object by analyzing a digital model of the object, wherein the digital model is based on a specification of the object in which the object is composed of a first three-dimensional printing material; predicting stress in the object based on the predicted thermal expansion; identifying a portion of the object based on the predicted thermal expansion exceeding a first predefined limit or the predicted stress exceeding a second predefined limit; performing simulations using different digital models of the object that correspond to different designs of the object that include one or more other three-dimensional printing materials at the portion, wherein a respective one of the simulations for a respective one of the different designs predicts thermal expansion and stress associated with the respective one of the different designs; and altering the specification of the object based on the simulations.

### BRIEF DESCRIPTION OF THE DRAWINGS

Aspects of the present invention are described in the detailed description which follows, in reference to the noted plurality of drawings by way of non-limiting examples of exemplary embodiments of the present invention.

FIG. 1 depicts a computing environment according to an embodiment of the present invention.

FIG. 2 shows a block diagram of an exemplary environment in accordance with aspects of the present invention.

FIG. 3 shows a flowchart of an exemplary method in accordance with aspects of the present invention.

FIGS. 4A, 4B, and 4C illustrate an exemplary use case in accordance with aspects of the present invention.

FIG. 5 shows a flowchart of an exemplary method in accordance with aspects of the present invention.

### DETAILED DESCRIPTION

Aspects of the present invention relate generally to three-dimensional (3D) printed objects. Thermal expansion in 3D printed objects can present a significant problem, as it often results in the creation of additional stress within the objects. When objects such as machine parts are subjected to temperature variations, their materials may expand or contract, leading to dimensional changes. This change in size can generate internal stresses within the parts, potentially compromising structural integrity and functionality.

The additional stress caused by thermal expansion can have several detrimental effects. Firstly, it may lead to deformation or distortion of the part, affecting its precise fit and alignment with other components or surfaces in a system. This misalignment can result in reduced performance or complete failure of the system in which the part is used. Secondly, the stress induced by thermal expansion can contribute to accelerated wear and fatigue of the part over time. The repeated expansion and contraction cycles caused by temperature changes can gradually weaken the part, ultimately leading to its premature failure. Therefore, understanding and mitigating the effects of thermal expansion is useful for ensuring the reliability and longevity of 3D printed objects used as parts in various applications such as machines.

Thermal expansion in parts can give rise to various problems, which can be attributed to factors such as improper cooling, operational temperature, and environmental temperature. One common issue is dimensional changes. When parts experience thermal expansion, their size can increase, leading to a mismatch with other components or tight-fitting areas. This can result in difficulties during assembly, reduced functionality, or even complete incompatibility with the intended system.

Another problem associated with thermal expansion is the generation of internal stress. As a parts heats up, its materials expands. If the expansion is uneven or restricted, it can create stress within the part. This internal stress can lead to deformation, warping, or even cracking of the part, ultimately affecting its structural integrity and performance.

Furthermore, thermal expansion can exacerbate issues related to thermal fatigue. The repeated expansion and contraction cycles due to temperature variations can weaken the part over time, making it more susceptible to fatigue failure. This can significantly reduce the lifespan and reliability of the part within a system such as a machine, necessitating more frequent replacements and maintenance.

Thermal expansion coefficients can differ among different materials, causing dimensional changes in 3D printed objects when exposed to heat, especially due to operational and environmental temperature variation. These changes can lead to additional stress and permanent deformation, particularly when using multiple materials.

To mitigate these problems, implementations of the invention consider thermal properties, appropriate material selection, and effective cooling strategies in the design and manufacturing of 3D printed objects in order to minimize the adverse effects of thermal expansion in such objects when such objects are used as parts in a system such as a machine. Embodiments provide a method and system to dynamically adapt the specification of a 3D object that is to be printed, preventing deformation resulting from thermal expansion.

In an exemplary embodiment, a system and method are configured to analyze a digital model of a 3D printed object, where the digital model is based on a specification of the object in which the object is composed of a first three-dimensional printing material. In this example, the system and method are configured to use the analysis to predict thermal expansion in the object and stress in the object based on the thermal expansion. In this example, using the predicted thermal expansion and stress, the system and method are configured to identify a portion of the object based on determining a threshold limit of thermal expansion is exceeded at the portion or determining a threshold limit of stress is exceeded at the portion. In this example, the system and method are configured to perform simulations using different digital models of the object that correspond to different designs of the object that include one or more other three-dimensional printing materials at the portion, wherein a respective one of the simulations for a respective one of the different designs predicts thermal expansion and resultant stress associated with the respective one of the different designs. In this example, the system and method are configured to alter the specification of the object based on the simulations, wherein an object printed according to the altered specification has less thermal expansion or stress at the identified portion. In this manner, embodiments may be used to reduce the adverse effects of thermal expansion in 3D printed objects. Implementations of the invention thus provide an improvement in the technical field of 3D printed objects.

In another exemplary embodiment, there is a method for dynamically adapting a 3D model to be printed, and a system for performing the method, wherein the method comprises: analyzing a digital model of an object to be 3D printed; determining whether a predicted thermal expansion of the object will cause an increase above a threshold limit of thermal stress on an adjacent 3D object; determining whether multiple materials are to be used on different portions of the object; executing a thermal expansion simulation of the object to evaluate stress generation due to uneven thermal expansion among the multiple materials; and altering specifications of the object including the materials to be used within an allowed thermal expansion coefficient such that thermal expansion is minimal. In this example, the executing the thermal expansion simulation may further comprise: determining whether the thermal expansion causes deformation in the object and/or the adjacent 3D object; and in response to determining the thermal expansion causes deformation, utilizing an elastic material on different potions of the 3D object such that the thermal expansion is absorbed by the elastic material. In this example, the analyzing the digital model may further comprise: considering properties of the materials to be used in the 3D printing; identifying a purpose of usage of the object including a relative position of the object; identifying a clearance between the object and the adjacent 3D object; and identifying a temperature variation due to operational and environmental parameters. In this example, the altering the specification of the object may further comprise: identifying appropriate materials within the allowed thermal expansion coefficient; adapting the clearance between the object and the adjacent 3D object; and identifying a required level of cooling such that thermal expansion is prevented. In this manner, embodiments may be used to reduce the adverse effects of thermal expansion in 3D printed objects. Implementations of the invention thus provide an improvement in the technical field of 3D printed objects.

Various aspects of the present disclosure are described by narrative text, flowcharts, block diagrams of computer systems and/or block diagrams of the machine logic included in computer program product (CPP) embodiments. With respect to any flowcharts, depending upon the technology involved, the operations can be performed in a different order than what is shown in a given flowchart. For example, again depending upon the technology involved, two operations shown in successive flowchart blocks may be performed in reverse order, as a single integrated step, concurrently, or in a manner at least partially overlapping in time.

A computer program product embodiment (“CPP embodiment” or “CPP”) is a term used in the present disclosure to describe any set of one, or more, storage media (also called “mediums”) collectively included in a set of one, or more, storage devices that collectively include machine readable code corresponding to instructions and/or data for performing computer operations specified in a given CPP claim. A “storage device” is any tangible device that can retain and store instructions for use by a computer processor. Without limitation, the computer readable storage medium may be an electronic storage medium, a magnetic storage medium, an optical storage medium, an electromagnetic storage medium, a semiconductor storage medium, a mechanical storage medium, or any suitable combination of the foregoing. Some known types of storage devices that include these mediums include: diskette, hard disk, random access memory (RAM), read-only memory (ROM), erasable programmable read-only memory (EPROM or Flash memory), static random access memory (SRAM), compact disc read-only memory (CD-ROM), digital versatile disk (DVD), memory stick, floppy disk, mechanically encoded device (such as punch cards or pits/lands formed in a major surface of a disc) or any suitable combination of the foregoing. A computer readable storage medium, as that term is used in the present disclosure, is not to be construed as storage in the form of transitory signals per se, such as radio waves or other freely propagating electromagnetic waves, electromagnetic waves propagating through a waveguide, light pulses passing through a fiber optic cable, electrical signals communicated through a wire, and/or other transmission media. As will be understood by those of skill in the art, data is typically moved at some occasional points in time during normal operations of a storage device, such as during access, de-fragmentation or garbage collection, but this does not render the storage device as transitory because the data is not transitory while it is stored.

Computing environment 100 contains an example of an environment for the execution of at least some of the computer code involved in performing the inventive methods, such as the dynamic adaptation code of block 200. In addition to block 200, computing environment 100 includes, for example, computer 101, wide area network (WAN) 102, end user device (EUD) 103, remote server 104, public cloud 105, and private cloud 106. In this embodiment, computer 101 includes processor set 110 (including processing circuitry 120 and cache 121), communication fabric 111, volatile memory 112, persistent storage 113 (including operating system 122 and block 200, as identified above), peripheral device set 114 (including user interface (UI) device set 123, storage 124, and Internet of Things (IoT) sensor set 125), and network module 115. Remote server 104 includes remote database 130. Public cloud 105 includes gateway 140, cloud orchestration module 141, host physical machine set 142, virtual machine set 143, and container set 144.

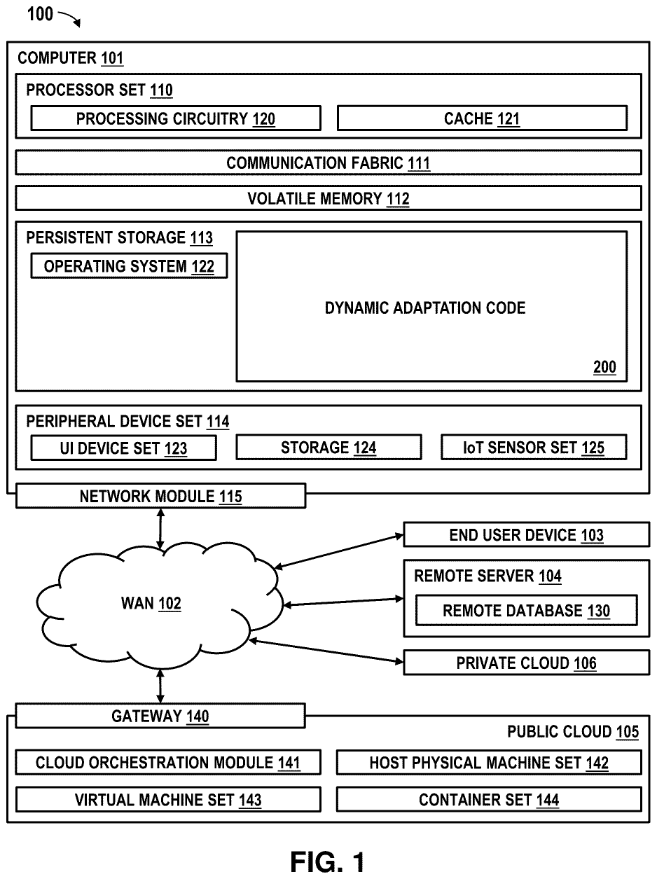

COMPUTER 101 may take the form of a desktop computer, laptop computer, tablet computer, smart phone, smart watch or other wearable computer, mainframe computer, quantum computer or any other form of computer or mobile device now known or to be developed in the future that is capable of running a program, accessing a network or querying a database, such as remote database 130. As is well understood in the art of computer technology, and depending upon the technology, performance of a computer-implemented method may be distributed among multiple computers and/or between multiple locations. On the other hand, in this presentation of computing environment 100, detailed discussion is focused on a single computer, specifically computer 101, to keep the presentation as simple as possible. Computer 101 may be located in a cloud, even though it is not shown in a cloud in FIG. 1. On the other hand, computer 101 is not required to be in a cloud except to any extent as may be affirmatively indicated.

PROCESSOR SET 110 includes one, or more, computer processors of any type now known or to be developed in the future. Processing circuitry 120 may be distributed over multiple packages, for example, multiple, coordinated integrated circuit chips. Processing circuitry 120 may implement multiple processor threads and/or multiple processor cores. Cache 121 is memory that is located in the processor chip package(s) and is typically used for data or code that should be available for rapid access by the threads or cores running on processor set 110. Cache memories are typically organized into multiple levels depending upon relative proximity to the processing circuitry. Alternatively, some, or all, of the cache for the processor set may be located “off chip.” In some computing environments, processor set 110 may be designed for working with qubits and performing quantum computing.

Computer readable program instructions are typically loaded onto computer 101 to cause a series of operational steps to be performed by processor set 110 of computer 101 and thereby effect a computer-implemented method, such that the instructions thus executed will instantiate the methods specified in flowcharts and/or narrative descriptions of computer-implemented methods included in this document (collectively referred to as “the inventive methods”). These computer readable program instructions are stored in various types of computer readable storage media, such as cache 121 and the other storage media discussed below. The program instructions, and associated data, are accessed by processor set 110 to control and direct performance of the inventive methods. In computing environment 100, at least some of the instructions for performing the inventive methods may be stored in block 200 in persistent storage 113.

COMMUNICATION FABRIC 111 is the signal conduction path that allows the various components of computer 101 to communicate with each other. Typically, this fabric is made of switches and electrically conductive paths, such as the switches and electrically conductive paths that make up busses, bridges, physical input/output ports and the like. Other types of signal communication paths may be used, such as fiber optic communication paths and/or wireless communication paths.

VOLATILE MEMORY 112 is any type of volatile memory now known or to be developed in the future. Examples include dynamic type random access memory (RAM) or static type RAM. Typically, volatile memory 112 is characterized by random access, but this is not required unless affirmatively indicated. In computer 101, the volatile memory 112 is located in a single package and is internal to computer 101, but, alternatively or additionally, the volatile memory may be distributed over multiple packages and/or located externally with respect to computer 101.

PERSISTENT STORAGE 113 is any form of non-volatile storage for computers that is now known or to be developed in the future. The non-volatility of this storage means that the stored data is maintained regardless of whether power is being supplied to computer 101 and/or directly to persistent storage 113. Persistent storage 113 may be a read only memory (ROM), but typically at least a portion of the persistent storage allows writing of data, deletion of data and re-writing of data. Some familiar forms of persistent storage include magnetic disks and solid state storage devices. Operating system 122 may take several forms, such as various known proprietary operating systems or open source Portable Operating System Interface type operating systems that employ a kernel. The code included in block 200 typically includes at least some of the computer code involved in performing the inventive methods.

PERIPHERAL DEVICE SET 114 includes the set of peripheral devices of computer 101. Data communication connections between the peripheral devices and the other components of computer 101 may be implemented in various ways, such as Bluetooth connections, Near-Field Communication (NFC) connections, connections made by cables (such as universal serial bus (USB) type cables), insertion type connections (for example, secure digital (SD) card), connections made through local area communication networks and even connections made through wide area networks such as the internet. In various embodiments, UI device set 123 may include components such as a display screen, speaker, microphone, wearable devices (such as goggles and smart watches), keyboard, mouse, printer, touchpad, game controllers, and haptic devices. Storage 124 is external storage, such as an external hard drive, or insertable storage, such as an SD card. Storage 124 may be persistent and/or volatile. In some embodiments, storage 124 may take the form of a quantum computing storage device for storing data in the form of qubits. In embodiments where computer 101 is required to have a large amount of storage (for example, where computer 101 locally stores and manages a large database) then this storage may be provided by peripheral storage devices designed for storing very large amounts of data, such as a storage area network (SAN) that is shared by multiple, geographically distributed computers. IoT sensor set 125 is made up of sensors that can be used in Internet of Things applications. For example, one sensor may be a thermometer and another sensor may be a motion detector.

NETWORK MODULE 115 is the collection of computer software, hardware, and firmware that allows computer 101 to communicate with other computers through WAN 102. Network module 115 may include hardware, such as modems or Wi-Fi signal transceivers, software for packetizing and/or de-packetizing data for communication network transmission, and/or web browser software for communicating data over the internet. In some embodiments, network control functions and network forwarding functions of network module 115 are performed on the same physical hardware device. In other embodiments (for example, embodiments that utilize software-defined networking (SDN)), the control functions and the forwarding functions of network module 115 are performed on physically separate devices, such that the control functions manage several different network hardware devices. Computer readable program instructions for performing the inventive methods can typically be downloaded to computer 101 from an external computer or external storage device through a network adapter card or network interface included in network module 115.

WAN 102 is any wide area network (for example, the internet) capable of communicating computer data over non-local distances by any technology for communicating computer data, now known or to be developed in the future. In some embodiments, the WAN 102 may be replaced and/or supplemented by local area networks (LANs) designed to communicate data between devices located in a local area, such as a Wi-Fi network. The WAN and/or LANs typically include computer hardware such as copper transmission cables, optical transmission fibers, wireless transmission, routers, firewalls, switches, gateway computers and edge servers.

END USER DEVICE (EUD) 103 is any computer system that is used and controlled by an end user (for example, a customer of an enterprise that operates computer 101), and may take any of the forms discussed above in connection with computer 101. EUD 103 typically receives helpful and useful data from the operations of computer 101. For example, in a hypothetical case where computer 101 is designed to provide a recommendation to an end user, this recommendation would typically be communicated from network module 115 of computer 101 through WAN 102 to EUD 103. In this way, EUD 103 can display, or otherwise present, the recommendation to an end user. In some embodiments, EUD 103 may be a client device, such as thin client, heavy client, mainframe computer, desktop computer and so on.

REMOTE SERVER 104 is any computer system that serves at least some data and/or functionality to computer 101. Remote server 104 may be controlled and used by the same entity that operates computer 101. Remote server 104 represents the machine(s) that collect and store helpful and useful data for use by other computers, such as computer 101. For example, in a hypothetical case where computer 101 is designed and programmed to provide a recommendation based on historical data, then this historical data may be provided to computer 101 from remote database 130 of remote server 104.

PUBLIC CLOUD 105 is any computer system available for use by multiple entities that provides on-demand availability of computer system resources and/or other computer capabilities, especially data storage (cloud storage) and computing power, without direct active management by the user. Cloud computing typically leverages sharing of resources to achieve coherence and economies of scale. The direct and active management of the computing resources of public cloud 105 is performed by the computer hardware and/or software of cloud orchestration module 141. The computing resources provided by public cloud 105 are typically implemented by virtual computing environments that run on various computers making up the computers of host physical machine set 142, which is the universe of physical computers in and/or available to public cloud 105. The virtual computing environments (VCEs) typically take the form of virtual machines from virtual machine set 143 and/or containers from container set 144. It is understood that these VCEs may be stored as images and may be transferred among and between the various physical machine hosts, either as images or after instantiation of the VCE. Cloud orchestration module 141 manages the transfer and storage of images, deploys new instantiations of VCEs and manages active instantiations of VCE deployments. Gateway 140 is the collection of computer software, hardware, and firmware that allows public cloud 105 to communicate through WAN 102.

Some further explanation of virtualized computing environments (VCEs) will now be provided. VCEs can be stored as “images.” A new active instance of the VCE can be instantiated from the image. Two familiar types of VCEs are virtual machines and containers. A container is a VCE that uses operating-system-level virtualization. This refers to an operating system feature in which the kernel allows the existence of multiple isolated user-space instances, called containers. These isolated user-space instances typically behave as real computers from the point of view of programs running in them. A computer program running on an ordinary operating system can utilize all resources of that computer, such as connected devices, files and folders, network shares, CPU power, and quantifiable hardware capabilities. However, programs running inside a container can only use the contents of the container and devices assigned to the container, a feature which is known as containerization.

PRIVATE CLOUD 106 is similar to public cloud 105, except that the computing resources are only available for use by a single enterprise. While private cloud 106 is depicted as being in communication with WAN 102, in other embodiments a private cloud may be disconnected from the internet entirely and only accessible through a local/private network. A hybrid cloud is a composition of multiple clouds of different types (for example, private, community or public cloud types), often respectively implemented by different vendors. Each of the multiple clouds remains a separate and discrete entity, but the larger hybrid cloud architecture is bound together by standardized or proprietary technology that enables orchestration, management, and/or data/application portability between the multiple constituent clouds. In this embodiment, public cloud 105 and private cloud 106 are both part of a larger hybrid cloud.

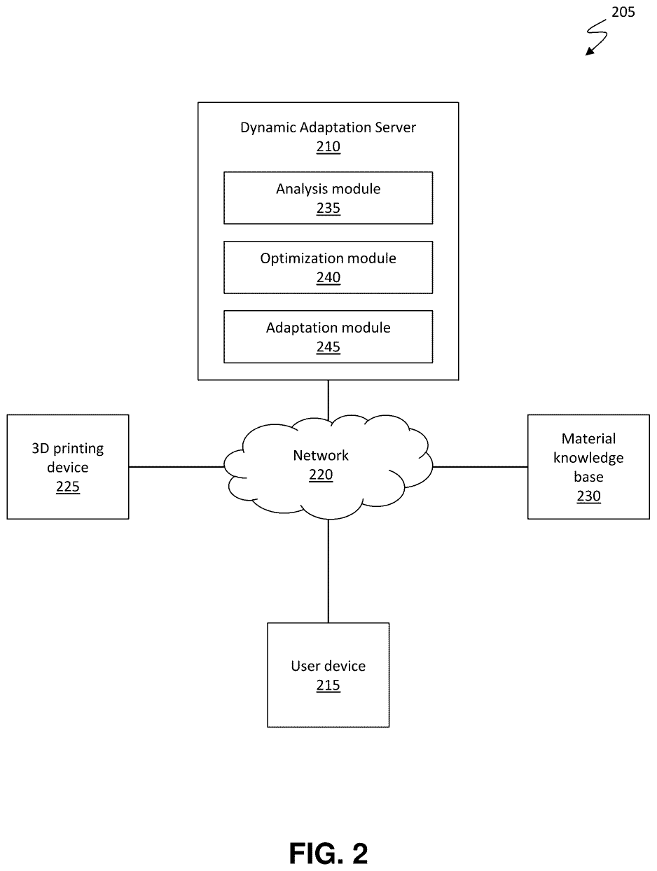

FIG. 2 shows a block diagram of an exemplary environment 205 in accordance with aspects of the invention. In embodiments, the environment 205 includes a dynamic adaptation server 210 comprising a computing system that is configured to perform operations described herein. In one example, the dynamic adaptation server 210 comprises one or more instances of the computer 101 of FIG. 1. In another example, the dynamic adaptation server 210 comprises one or more virtual machines or one or more containers running one or more instances of the computer 101 of FIG. 1.

In various embodiments, the dynamic adaptation server 210 communicates with a user device 215 via a network 220. The user device 215 comprises a computing device such as the EUD 103 of FIG. 1. The network 220 may comprise the WAN 102 of FIG. 1. In embodiments, the user device 215 communicates with a 3D printing device 225 that is configured to manufacture objects using 3D printing. The 3D printing device 225 may utilize a 3D printing technology such as material extrusion, binder jetting, direct energy deposition, material jetting, powder bed fusion, sheet lamination, or vat polymerization, for example and without limitation. The user device 215 may communicate with the 3D printing device 225 via the network 220 or via a direct connection between the user device 215 and the 3D printing device 225. The user device 215 may include software (e.g., an application) that is configured to send instructions to the 3D printing device 225 wherein the instructions cause the 3D printing device 225 to print an object according to a specification.

A material knowledge base 230 may be used to store data that defines properties of materials that may be used by the 3D printing device 225 to manufacture objects using 3D printing. Properties of materials defined in the material knowledge base 230 may include but are not limited to: coefficient of thermal expansion (also called thermal expansion coefficient); Young's modulus; Poisson's ratio; density; melting point; tensile strength; and hardness. The material knowledge base 230 may comprise one or more instances of a remote server 104 or remote database 130 of FIG. 1. The dynamic adaptation server 210 may access the material knowledge base 230 via the network 220.

In embodiments, the dynamic adaptation server 210 of FIG. 2 comprises an analysis module 235, an optimization module 240, and an adaptation module 245, each of which may comprise modules of the code of block 200 of FIG. 1. Such modules may include routines, programs, objects, components, logic, data structures, and so on that perform particular tasks or implement particular data types that the code of block 200 uses to carry out the functions and/or methodologies of embodiments of the invention as described herein. These modules of the code of block 200 are executable by the processing circuitry 120 of FIG. 1 to perform the inventive methods as described herein. The dynamic adaptation server 210 may include additional or fewer modules than those shown in FIG. 2. In embodiments, separate modules may be integrated into a single module. Additionally, or alternatively, a single module may be implemented as multiple modules. Moreover, the quantity of devices and/or networks in the environment is not limited to what is shown in FIG. 2. In practice, the environment may include additional devices and/or networks; fewer devices and/or networks; different devices and/or networks; or differently arranged devices and/or networks than illustrated in FIG. 2.

In accordance with aspects of the invention, the analysis module 235 is configured to: predict thermal expansion in an object by analyzing a digital model of the object, wherein the digital model is based on a specification of the object in which the object is composed of a first three-dimensional printing material; predict stress in the object based on the predicted thermal expansion; and identify a portion of the object based on predicted thermal expansion or the predicted stress. In embodiments, the analysis module 235 receives the specification of the object from or via the user device 215. In one example, the user device 215 transmits data to dynamic adaptation server 210 where the data defines the specification of the object. The data defining the specification may be in a predefined format, such as a predefined file format that is prescribed by the dynamic adaptation server 210 and usable by the analysis module 235 (e.g., via a predefined application program interface or predefined web service). The data defining the specification may include, for example and without limitation: dimensions of the object; a material of which the object is composed; a specification of a system that comprises the object, the specification including dimensions of other objects in the system, positions of other objects in the system relative to the object, and how the object is used or operates within the system relative to other objects in the system; and environmental parameters within the system such as temperature, humidity, and/or pressure within the system at different locations and different times.

With continued reference to FIG. 2, and in accordance with further aspects of the invention, the analysis module 235 is configured to create the digital model of the object based on the specification of the object. In one example, the analysis module 235 is programmed with logic that converts the data in the predefined file format to a digital model. In embodiments, the analysis module 235 is configured to predict thermal expansion and stress in the object by performing thermal expansion analysis and stress analysis using the digital model. In one example, the analysis module 235 is programmed with logic that performs finite element analysis on the digital model, where the finite element analysis is specifically configured to analyze the digital model to determine thermal expansion of the object and stress in the object due to the thermal expansion. In embodiments, the analysis module 235 determines a material of which the object is composed from the specification, obtains properties of this material from the material knowledge base 230, and uses these properties in the finite element analysis. In embodiments, the analysis module 235 identifies a portion of the object based on the thermal expansion analysis and stress generation analysis. In one example, the analysis module 235 identifies the portion of the object based on determining that a threshold limit of thermal expansion is exceeded at the portion. In another example, the analysis module 235 identifies the portion of the object based on determining a threshold limit of stress is exceeded at the portion. The threshold limit of thermal expansion may be a first predefined limit that is a user configurable option, and the threshold limit of stress may be a second predefined limit that is a user configurable option.

In accordance with aspects of the invention, the optimization module 240 is configured to perform simulations using different digital models of the object that correspond to different designs of the object that include one or more other 3D printing materials at the identified portion, wherein a respective one of the simulations for a respective one of the different designs predict thermal expansion and stress in the object associated with the respective one of the different designs. In embodiments, based on the analysis module 235 identifying a portion of the object that has thermal expansion and/or stress that exceeds a threshold limit, the optimization module 240 runs simulations on different designs of the same object to determine whether one or more of the different designs has an acceptable amount of thermal expansion and/or stress at the identified portion (e.g., thermal expansion and/or stress that does not exceed the threshold limit). In embodiments, the optimization module 240 creates the different designs of the object using one or more alternate 3D printing materials that are usable in the 3D printing device 225 and that are different than the material of the object as defined in the specification of the object. A list of alternate materials may be provided to the dynamic adaptation server 210 via the user device 215 or the 3D printing device 225, these alternate materials being materials that are compatible with the 3D printing device 225 and that are available for use by the 3D printing device 225. In embodiments, the optimization module 240 creates a respective different design of the object by substituting one or more of the alternate 3D printing materials for the original material of the object at one or more locations in the object. The one or more locations may comprise the entirety of the object or less than the entirety of the object. In embodiments, the optimization module 240 provides the respective different designs to the analysis module 235, which determines thermal expansion and stress associated with the respective ones of the different designs in the manner described above (e.g., by obtaining properties of materials from the material knowledge base 230 and performing finite element analysis using the respective designs and material properties). In embodiments, the analysis module 235 provides the determined thermal expansion and stress values for each of the different designs to the optimization module 240, which determines an optimal design based on the these values. In one example, the optimization module 240 determines the optimal design based on the one of the designs that minimizes the thermal expansion and/or stress at the identified portion.

In accordance with aspects of the invention, the adaptation module 245 is configured to alter the specification of the object based on the simulations. In embodiments, the adaptation module 245 receives data defining the optimal design from the optimization module 240 and alters the original specification of the object based on the optimal design. In one example, the adaptation module 245 alters the specification of the object by changing the 3D printing material at one or more locations in the object (e.g., changing the 3D printing material from the original material defined in the original specification to an alternate material defined in the optimal design that was determined via the simulations). In another example, the adaptation module 245 alters the specification of the object by changing a physical dimension of the object, e.g., to achieve a defined clearance between the object and another object on the system. In another example, the adaptation module 245 alters the specification of the object by changing an environmental parameter of the system, e.g., by identifying a required level of cooling in the system such that thermal expansion of the object is reduced to an acceptable level. The 3D printing device 225 may then be used to manufacture the object using 3D printing and according to the altered specification.

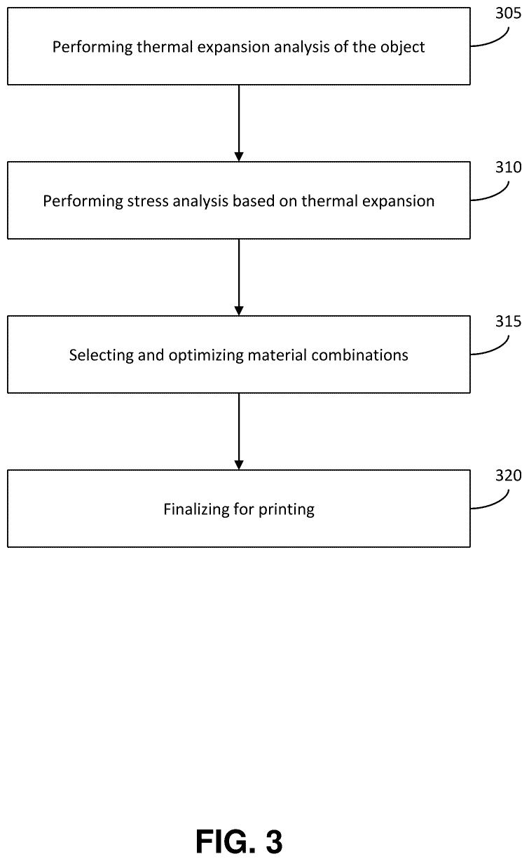

FIG. 3 shows a flowchart of an exemplary method in accordance with aspects of the present invention. Steps of the method may be carried out in the environment of FIG. 2 and are described with reference to elements depicted in FIG. 2.

At step 305, the system performs a thermal expansion analysis of the object. In embodiments, and as described with respect to FIG. 2, the analysis module 235 receives a specification of the object from the user device 215 and determines thermal expansion at locations of the object based on the specification and using computer-based modeling such as finite element analysis. In various embodiments, the analysis module 235 performs a thermal expansion analysis of the object by analyzing its material properties and applying mathematical models to predict the dimensional changes that occur when the object is subjected to temperature variations. In one example, the analysis module 235 receives the specification of the object that is to be printed and creates a digital model of the object based on the specification. In another example, the analysis module 235 receives the digital model of the object, e.g., from the user device 215. In embodiments, the analysis module 235 analyzes the digital model including the shape of the 3D object (e.g., such as dimensions of the object, whether the object is solid or hollow, thicknesses of portions of the object, etc.).

In embodiments, the analysis module 235 considers the material properties of the material defined in the specification for 3D printing the object. These properties may be obtained from the material knowledge base 230 and may include the coefficient of thermal expansion (CTE) and the Young's modulus of the material. The CTE describes how the material expands or contracts with temperature changes, while the Young's modulus represents its stiffness.

In embodiments, the analysis module 235 imports the digital model into a finite element analysis (FEA) software package. This software divides the object defined in the model into a mesh of small elements for analysis. The software is specifically configured to perform thermal analysis and solve nonlinear problems.

With continued reference to step 305, the analysis module 235 may be configured to consider boundary conditions in the thermal expansion analysis. The boundary conditions may be determined from information included in the specification and may comprise one or more of: properties of the materials that will be used for 3D printing (thermal expansion coefficient); purpose of usage of the object in the system including relation of the object to other objects in the system; clearance between the object and other objects in the system; temperature variation due of operational and environmental parameters of the system; and different materials on different portions of the object.

In embodiments, the analysis module 235 assigns the appropriate material properties to the mesh elements based on the material used for 3D printing, e.g., as defined in the specification. In one example, the finite element analysis uses the CTE value of the material to define how the material expands or contracts with temperature changes and uses the Young's modulus of the material to define the material's stiffness and how it resists deformation. In this example, the analysis module 235 performs the thermal deformation analysis using the FEA software. The software may be specially configured to solve the equations that describe the heat transfer within the object and the resulting thermal expansion, and to calculate the displacement or dimensional changes of the object based on thermal expansion resulting from the specified temperature variations. In various embodiments, the software provides visualizations of the displacement or strain distribution within the object, e.g., to the user device 215, and identifies the deviation from the original shape and dimension.

With continued reference to FIG. 3, at step 310 the system performs a stress analysis of the object based on the thermal expansion analysis from step 305. In embodiments, and as described with respect to FIG. 2, the analysis module 235 determines magnitudes and locations of stress that is generated within the object resulting from the thermal expansion of the object that was determined at step 305.

In various embodiments, the analysis module 235 determines stress in the object as a result of deformation of the object caused by thermal expansion of the object. In one example, the deformation of the object due to thermal expansion does not result in the object coming into physical contact with another object in the system. In this example, the analysis module 235 determines stress in the object based solely on the object itself. In another example, the deformation of the object due to thermal expansion results in the object coming into physical contact with another object in the system. In this example, the analysis module 235 determines stress in the object based on the deformation of the object itself and also based on the physical contact of the object with the other object. In this example, the analysis module 235 determines the geometry of the other object and properties of the material(s) of the other object and uses the geometry and properties in the stress analysis. Properties such as Young's modulus and Poisson's ratio of the material(s) of the other object will have an effect on the stresses generated in the object when the object deforms and comes into contact with the other object, and the analysis module 235 is configured to account for this effect when performing the stress analysis. Moreover, the geometry of the object and the geometry of the other object will have an effect on the stresses generated in the object when the object deforms and comes into contact with the other object, and the analysis module 235 is configured to account for this effect when performing the stress analysis. In one example, the finite element analysis performed by the analysis module 235 takes these factors into account when calculating the stresses and deformations based on the thermal expansion and the applied loads.

Still referring to step 310, in embodiments the analysis module 235 is configured to analyze the results obtained from the FEA software. In one example, the analysis module 235 reviews the stress distribution within the object and adjacent objects and, based on this review, the analysis module 235 identifies regions of high stress or potential failure points. For example, step 310 may comprise the analysis module 235 using the results from the thermal expansion analysis and stress analysis to identify a portion of the object based on determining a threshold limit of thermal expansion is exceeded at the portion or determining a threshold limit of stress is exceeded at the portion, e.g., as described with respect to FIG. 2. In various embodiments, the analysis module 235 evaluates whether the stress levels exceed the material's yield strength or if the design does not meet the requirements of the specification, in which case the process proceeds to step 315 to select one or more alternate materials for one or more portions of the object from a material specification repository.

At step 315, the system selects and optimizes material combinations for the object. In embodiments, step 315 is performed to select different combinations of materials that can be used for portions of the object, and running simulations with the different combinations of materials, with the goal of identifying an alternate design of the object that avoids cracks and other structural issues associated with the object due to thermal expansion. In one example, step 315 comprises the optimization module 240 performing multiple different simulations using different digital models of the object that correspond to different designs of the object that include one or more alternate 3D printing materials at an identified portion of the object. In this example, a respective one of the simulations for a respective one of the different designs determines thermal expansion and stress generation associated with the respective one of the different designs.

In accordance with aspects of the invention, step 315 comprises the optimization module 240 performing a material selection operation based on material properties. In this operation, the optimization module 240 accesses the material knowledge base 230 to obtain data on a range of suitable alternate materials for 3D printing the object. The material properties, including the thermal expansion coefficient, Young's modulus, Poisson's ratio, thermal conductivity, and crack resistance, may be obtained for usage in the simulations.

In accordance with further aspects of the invention, step 315 comprises the optimization module 240 performing a material combination generation operation. In this operation, the optimization module 240 generates a range of different material combinations for the object, e.g., by creating alternate designs of the object that include one or more of the alternate material at one or more locations of the object. In embodiments, the optimization module 240 creates the alternate designs based on the thermal expansion coefficients of different materials and their compatibility with each other for the purpose of finding combinations of materials and locations in the object that mitigate the effects of thermal expansion and contraction, reducing the likelihood of cracks forming in the object.

In accordance with further aspects of the invention, step 315 comprises the dynamic adaptation server 210 performing multi-material thermal expansion simulations. In these simulations, the optimization module 240 tests each potential combination of materials using the thermal expansion analysis of step 305. In embodiments, the optimization module 240 provides respective ones of the alternate designs of the object (e.g., created at the material combination generation operation) to the analysis module 235, which performs a thermal analysis on the alternate designs, e.g., in a manner similar to that performed with the original design of the object at step 305. In this manner, the system uses the simulations to determine how different materials at different locations of the object affect (e.g., change) the thermal expansion of the object, e.g., compared to the thermal expansion determined for the original design of the object.

In accordance with further aspects of the invention, step 315 comprises the dynamic adaptation server 210 performing multi-material stress analysis. In this operation, following the multi-material thermal expansion simulations, the system performs a stress analysis for each material combination. In embodiments, for each respective alternate design that was simulated in to determine thermal expansion, the analysis module 235 uses the thermal expansion for the respective alternate design to determine stress in the object associated with the alternate design, e.g., in a manner similar to that performed with the original design of the object at step 310.

In accordance with further aspects of the invention, step 315 comprises the optimization module 240 performing a material combination evaluation operation. In this operation, the optimization module 240 evaluates the results from the thermal expansion simulations and stress analyses for each material combination, e.g., for each respective alternate design, to identify combinations of materials that result in the lowest possible stress generation and deformation, thus preventing crack formation in the object.

In accordance with further aspects of the invention, step 315 comprises the optimization module 240 performing a material combination optimization operation. In this operation, based on the evaluations, the optimization module 240 optimizes the material combination for the digital model of the object. The optimization process may involve adjusting the proportions of different materials used, their distribution within the model, or swapping one material for another with superior properties.

With continued reference to FIG. 3, at step 320 the system finalizes the specification of the object for printing. In embodiments, step 320 involves finalizing the specification of the object to be printed based on the optimized material combination determines at step 315. Step 320 may be performed by the adaptation module 245 and may comprise the adaptation module 245 receiving data defining the optimal design from the optimization module 240 (e.g., as determined at step 315) and altering the original specification of the object based on the optimal design, such that the 3D printing device may use the altered specification to print the 3D object.

In accordance with aspects of the invention, step 320 comprises the adaptation module 245 performing an operation to update the specification of the object. In this operation, the adaptation module 245 alters the specification of the object based on the optimal material combination determined at step 315. This may involve assigning different materials to different parts of the object or adjusting the geometry of the object to accommodate the properties of the materials

In accordance with aspects of the invention, step 320 comprises the adaptation module 245 performing an operation to verify the specification. In this operation, the adaptation module 245 re-analyzes the altered specification using the thermal expansion analysis and stress analysis of steps 305 and 310. This verification process ensures that the changes have indeed mitigated the thermal expansion issues.

In accordance with aspects of the invention, step 320 comprises the adaptation module 245 performing a final validation operation. In this operation, once the altered specification passes the verification, it is considered ready for 3D printing. In one example, the dynamic adaptation server 210 provides the user with the final model and the corresponding materials list, e.g., via the user device 215. The user can then proceed to print the object using the 3D printing device 225 and the altered specification, with confidence that the object will withstand the expected thermal stresses. In another example, the dynamic adaptation server 210 and the 3D printing device 225 are owned or controlled or operated by a same entity, and the dynamic adaptation server 210 sends an instruction to the 3D printing device 225 to print the object according to the altered specification.

In accordance with aspects of the invention, step 320 comprises the adaptation module 245 performing an operation to continually update documentation. In this operation, the adaptation module 245 documents all changes, simulations, and decisions made throughout this process. This record can be useful for future reference, ensuring consistency and allowing for further optimization if necessary.

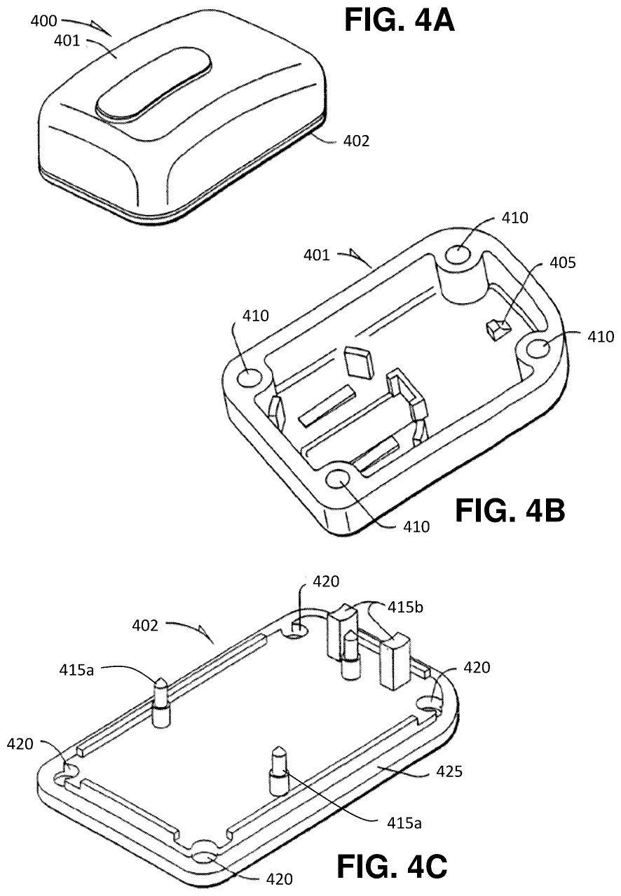

FIGS. 4A, 4B, and 4C illustrate an exemplary use case in accordance with aspects of the present invention. Operations involving the use case may be carried out in the environment of FIG. 2 and are described with reference to elements depicted in FIG. 2.

FIG. 4A shows a system that comprises a housing 400 in this example. The housing 400 comprises an upper part 401 and a lower part 402 shown individually in FIGS. 4B and 4C, respectively. Each of the upper part 401 and the lower part 402 are objects that may be manufactured by 3D printing. In this example, and as shown in FIG. 4B, the upper part 401 includes a shell that defines an interior cavity and that includes various protrusions 405 and holes 410. In this example, and as shown in FIG. 4C, the lower part 402 includes a baseplate that includes various protrusions 415a and 415b, holes 420, and a flange 425. In this example, the housing 400 houses electronics (not shown) that generate different amounts of heat during different phases of their normal and intended operation.

With continued reference to the use case shown in FIGS. 4A-C, the user device 215 of FIG. 2 includes one or more files that define a specification of the lower part 402. The specification includes data that defines: dimensions of the lower part 402; a material of which the lower part 402 is composed; a specification of the housing 400 that comprises the lower part 402, the specification of the housing 400 including dimensions of other objects in the system including the upper part 401, positions of the upper part 401 relative to the lower part 402 when the parts are assembled, and how the lower part 402 is operates within the system relative to other objects in the system such as the upper part 401 and the electronics; and environmental parameters within the system such as temperature, humidity, and pressure in and around the housing 400 at different locations and different times (e.g. as a result of ambient temperature, humidity, and pressure outside the housing 402 and internal temperature, humidity, and pressure inside the housing 402). In this example, the specification of the lower part 402 defines a first material (e.g., acrylonitrile butadiene styrene (ABS)) for 3D printing of the entirety of each of the lower part 402 and the upper part 401

Still referring to the example shown in FIGS. 4A-C, in this example the user device 215 sends the specification to the dynamic adaptation server 210 of FIG. 2. The dynamic adaptation server 210 uses the specification to create a digital model of the lower part 402 and uses the digital model to perform a thermal expansion analysis on the lower part 402 and a stress analysis based on the thermal expansion analysis, e.g., in the manner described at steps 305 and 310 of FIG. 3. In this example, based on the thermal expansion analysis and stress analysis of the lower part 402, the dynamic adaptation server 210 identifies a portion (e.g.., protrusions 415a) of the lower part 402 where the stress caused by the thermal expansion exceeds a predefined limit. In this example, based on identifying the portion, the dynamic adaptation server 210 runs simulations with different designs of the lower part 402 using one or more different materials at different locations of the lower part 402, e.g., in the manner described at step 315 of FIG. 3.

In this example, in a first one of the simulations, the dynamic adaptation server 210 changes the design of the lower part 402 such that the protrusions 415a are composed of polylactic acid (PLA) and the protrusions 415b are composed of high impact polystyrene (HIPS), with the remainder of the lower part 402 being composed of ABS and with the entirety of the upper part 401 being composed of ABS. In this example, in a second one of the simulations, the dynamic adaptation server 210 changes the design of the lower part 402 such that the protrusions 415a are composed of PLA, the protrusions 415b and the remainder of the lower part 402 are composed of ABS, the protrusions 405 of the upper part 401 are composed of PLA, and the remainder of the upper part 401 is composed of HIPS. These two simulations are examples of many different simulations that the dynamic adaptation server 210 may run at step 315 by creating different designs of the lower part 402 using different materials at different locations of the lower part 402. Other simulations may include changing other parameters, such as adding forced cooling to an environment around the housing 400 that changes the temperature around the environment around the housing 400. Other simulations may include changing other parameters, such as changing the dimensions of the protrusions 415a and 415b so that there is more clearance between the protrusions 415a and 415b and the upper part 401 when the upper part 401 and the lower part 402 are connected to form the housing 400. Other simulations may be based on alternate designs that include gradients of mixtures of different ones of the materials at locations in the object. For example, instead of the entirety of the protrusion 415a being composed of ABS, in one alternate design, a proximal base portion of the protrusion 415a may be composed of a mixture comprising 60% ABS and 40% PLA, a middle portion of the protrusion 415a may be composed of a mixture comprising 40% ABS and 60% PLA, and a distal end portion of the protrusion 415 a may be composed of 100% PLA.

With continued reference to the example shown in FIGS. 4A-C, in this example the dynamic adaptation server 210 compares the results of the simulations and determines that the design of the object associated with the first one of the simulations is the optimal design for reducing the amount of stress generated by thermal expansion at the identified location. In this example, the dynamic adaptation server 210 alters the specification based on this optimal design, e.g., in the manner described at step 320 of FIG. 3. In particular, the dynamic adaptation server 210 alters the specification to indicate that the protrusions 415a of the lower part 402 are composed of PLA, the protrusions 415b of the lower part 402 are composed of HIPS, the remainder of the lower part 402 is composed of ABS, and the entirety of the upper part 401 being composed of ABS. In one implementation of this example, the dynamic adaptation server 210 sends the altered specification to the user device 215 so that the user device 215 can initiate printing the lower part 402 on the 3D printing device using the altered specification. In another implementation of this example, the dynamic adaptation server 210 sends instructions including the altered specification to the 3D printing device 225 causing the 3D printing device 225 to print the lower part 402 using the altered specification.

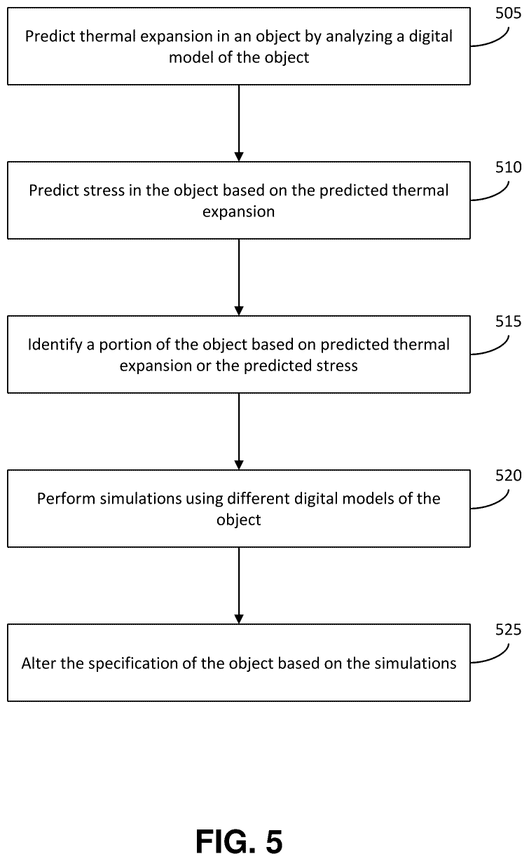

FIG. 5 shows a flowchart of an exemplary method in accordance with aspects of the present invention. Steps of the method may be carried out in the environment of FIG. 2 and are described with reference to elements depicted in FIG. 2.

At step 505, the system predicts thermal expansion in an object by analyzing a digital model of the object. In embodiments, the digital model is based on a specification of the object in which the object is composed of a first three-dimensional printing material. At step 510, the system predicts stress in the object based on the predicted thermal expansion. At step 515, the system identifies a portion of the object based on predicted thermal expansion or the predicted stress. In embodiments, the analysis module 235 performs steps 505, 510, and 515 in the manner described with respect to FIGS. 2 and 3.

At step 520, the system performs simulations using different digital models of the object that correspond to different designs of the object that include one or more other three-dimensional printing materials at the portion. In embodiments, a respective one of the simulations for a respective one of the different designs predicts thermal expansion and stress associated with the respective one of the different designs. In embodiments, the optimization module 240 performs step 520 in the manner described with respect to FIGS. 2 and 3.

At step 525, the system alters the specification of the object based on the simulations. In embodiments, the adaptation module 245 performs step 525 in the manner described with respect to FIGS. 2 and 3.

In embodiments, the method of FIG. 5 further comprises manufacturing the object using three-dimensional printing and according to the altered specification. The three-dimensional printing may comprise one selected from a group consisting of: material extrusion; binder jetting; direct energy deposition; material jetting; powder bed fusion; sheet lamination; and vat polymerization.

In embodiments of the method of FIG. 5, the first three-dimensional printing material has a first coefficient of thermal expansion, and respective ones of the one or more other three-dimensional printing materials are different than the first three-dimensional printing material and have respective coefficients of thermal expansion that are different than the first coefficient of thermal expansion.

In embodiments of the method of FIG. 5, the identifying the portion of the object comprises determining a threshold limit of thermal expansion is exceeded at the portion.

In embodiments of the method of FIG. 5, the identifying the portion of the object comprises determining a threshold limit of stress is exceeded at the portion.

In embodiments, the method of FIG. 5 further comprises analyzing a system that includes the object, wherein the analyzing includes: analyzing properties of three-dimensional printing materials used to manufacture objects in the system; identifying a purpose of usage of the object in the system; identifying a clearance between the object and an adjacent object in a system; and identifying a temperature variation in the object due to operational and environmental parameters associated with the system.

In embodiments of the method of FIG. 5, the altering the specification of the object is based on the analyzing the system and comprises one or more selected from a group consisting of: changing the specification to include one or more of the one or more other materials at the portion; changing the clearance between the object and an adjacent object in a system; and identifying a level of cooling associated with the object.

As set forth in the foregoing description, in various embodiments, the system analyzes a digital model of the object that is to be printed based on: considering properties of the materials will be used for 3D printing (e.g., thermal expansion coefficient); purpose of usage (e.g., where the object is to be assembled relative to adjacent objects); available clearance between the object adjacent objects (e.g., where it will be assembled); and temperature variations due to operational and environmental parameters. In this manner, implementations may be used to predict how much thermal expansion will happen in the object and if the same will create more than a threshold limit of thermal stress in the object. Based on this, the system is configured in various embodiments to alter the specification of the object by changing one or more of: materials used in manufacturing the object, with allowed thermal expansion coefficient; level of clearance between the object and adjacent objects so that the stress can be avoided; and level cooling, so that the thermal expansion can be prevented.

As set forth in the foregoing description, in various embodiments, the system determines whether multiple materials may be used for printing different portions of the object. In embodiments, the system performs thermal expansion simulation of different designs of the object to evaluate additional stress generation due to uneven thermal expansion among the multiple materials of the object. In embodiments, through an optimization routine used with the results of the simulations, including simulations that involve multi-material mixing, the system determines multiple materials to be used to print different portions of the object. In some embodiments, based on determining that the thermal expansion of the object can create deformation that causes physical interference between the object and an adjacent object, the system uses appropriate types of 3D printing material (e.g., highly elastic materials) on different portion of the object so that the thermal expansion can be absorbed by the highly elastic materials.

As set forth in the foregoing description, in various embodiments, the system analyzes the digital model of the object including material parameters and the distribution of multiple different materials on different portions of the object. Based on this, the system determines whether a particular design of he object may be used in a system (such as a machine) without causing adverse effects in the system.

As set forth in the foregoing description, in various embodiments, the system dynamically adapts the 3D model of the object that is to be printed based on the predicted amount of stress generation due to thermal expansion. In various embodiments, the system integrates advanced computational capabilities, such as thermal expansion simulation and stress analysis, to predict and mitigate the detrimental effects of thermal expansion. In implementations, the system considers several factors, including material properties, intended usage, thermal conditions, and more to tailor the specifications of the 3D model of the object to be printed. In this manner, embodiments may be used to identify the potential issues with the thermal expansion of material of the object and make changes in the 3D model, thereby ensuring the longevity and performance of the 3D printed part.

As set forth in the foregoing description, in various embodiments, there is a system for performing thermal expansion simulation of a 3D object to be printed, where the system analyzes a 3D model of the object, considers material properties and temperature variations, divides the object into a mesh of small elements for analysis using finite element analysis software, and predicts dimensional changes due to thermal expansion. In embodiments, the system performs stress simulation on the object due to thermal expansion, where the system identifies potential displacement or dimensional changes, considers adjacent objects that may interact due to thermal expansion, and executes a stress analysis using the material properties and loads applied to predict regions of high stress or potential failure points. In embodiments there is a method for selecting and optimizing combinations of materials based on the stress simulation and thermal expansion simulation results, where the system generates a range of potential material combinations, tests each combination using the thermal expansion simulation and stress analysis, evaluates each combination's performance, and updates the 3D model of the object based on the optimal material combination before finalizing the model for printing.

In embodiments, a service provider could offer to perform the processes described herein. In this case, the service provider can create, maintain, deploy, support, etc., the computer infrastructure that performs the process steps in accordance with aspects of the invention for one or more customers. These customers may be, for example, any business that uses technology. In return, the service provider can receive payment from the customer(s) under a subscription and/or fee agreement and/or the service provider can receive payment from the sale of advertising content to one or more third parties.

In still additional embodiments, implementations provide a computer-implemented method, via a network. In this case, a computer infrastructure, such as computer 101 of FIG. 1, can be provided and one or more systems for performing the processes in accordance with aspects of the invention can be obtained (e.g., created, purchased, used, modified, etc.) and deployed to the computer infrastructure. To this extent, the deployment of a system can comprise one or more of: (1) installing program code on a computing device, such as computer 101 of FIG. 1, from a computer readable medium; (2) adding one or more computing devices to the computer infrastructure; and (3) incorporating and/or modifying one or more existing systems of the computer infrastructure to enable the computer infrastructure to perform the processes in accordance with aspects of the invention.

The descriptions of the various embodiments of the present invention have been presented for purposes of illustration, but are not intended to be exhaustive or limited to the embodiments disclosed. Many modifications and variations will be apparent to those of ordinary skill in the art without departing from the scope and spirit of the described embodiments. The terminology used herein was chosen to best explain the principles of the embodiments, the practical application or technical improvement over technologies found in the marketplace, or to enable others of ordinary skill in the art to understand the embodiments disclosed herein.

What is claimed is:

1. A computer-implemented method, comprising:
predicting thermal expansion in an object by analyzing a digital model of the object, wherein the digital model is based on a specification of the object in which the object is composed of a first three-dimensional printing material;
predicting stress in the object based on the predicted thermal expansion;
identifying a portion of the object based on the predicted thermal expansion or the predicted stress;
performing simulations using different digital models of the object that correspond to different designs of the object that include one or more other three-dimensional printing materials at the portion, wherein a respective one of the simulations for a respective one of the different designs predicts thermal expansion and stress associated with the respective one of the different designs; and
altering the specification of the object based on the simulations.

2. The computer-implemented method of claim 1, further comprising manufacturing the object using three-dimensional printing and according to the altered specification.

3. The computer-implemented method of claim 2, wherein the three-dimensional printing comprises one selected from a group consisting of: material extrusion; binder jetting; direct energy deposition; material jetting; powder bed fusion; sheet lamination; and vat polymerization.

4. The computer-implemented method of claim 1, wherein:
the first three-dimensional printing material has a first coefficient of thermal expansion; and
respective ones of the one or more other three-dimensional printing materials are different than the first three-dimensional printing material and have respective coefficients of thermal expansion that are different than the first coefficient of thermal expansion.

5. The computer-implemented method of claim 1, wherein the identifying the portion of the object comprises determining a threshold limit of thermal expansion is exceeded at the portion.

6. The computer-implemented method of claim 1, wherein the identifying the portion of the object comprises determining a threshold limit of stress is exceeded at the portion.

7. The computer-implemented method of claim 1, further comprising analyzing a system that includes the object, wherein the analyzing includes:
analyzing properties of three-dimensional printing materials used to manufacture objects in the system;
identifying a purpose of usage of the object in the system;
identifying a clearance between the object and an adjacent object in a system; and
identifying a temperature variation in the object due to operational and environmental parameters associated with the system.

8. The computer-implemented method of claim 7, wherein the altering the specification of the object is based on the analyzing the system and comprises one or more selected from a group consisting of:
changing the specification to include one or more of the one or more other materials at the portion;
changing the clearance between the object and an adjacent object in a system; and
identifying a level of cooling associated with the object.

9. A computer program product comprising:
one or more computer-readable storage media; and
program instructions stored on the one or more computer-readable storage media to perform operations comprising:
predicting thermal expansion in an object by analyzing a digital model of the object using finite element analysis, wherein the digital model is based on a specification of the object in which the object is composed of a first three-dimensional printing material;
predicting stress in the object based on the predicted thermal expansion;
identifying a portion of the object based on the predicted thermal expansion or the predicted stress;
performing simulations using different digital models of the object that correspond to different designs of the object that include one or more other three-dimensional printing materials at the portion, wherein a respective one of the simulations for a respective one of the different designs predicts thermal expansion and stress associated with the respective one of the different designs; and
altering the specification of the object based on the simulations.

10. The computer program product of claim 9, wherein:
the first three-dimensional printing material has a first coefficient of thermal expansion; and
respective ones of the one or more other three-dimensional printing materials are different than the first three-dimensional printing material and have respective coefficients of thermal expansion that are different than the first coefficient of thermal expansion.

11. The computer program product of claim 9, wherein the identifying the portion of the object comprises determining a threshold limit of thermal expansion is exceeded at the portion.

12. The computer program product of claim 9, wherein the identifying the portion of the object comprises determining a threshold limit of stress is exceeded at the portion.

13. The computer program product of claim 9, wherein the operations further comprise analyzing a system that includes the object, wherein the analyzing includes one or more selected from a group consisting of:
analyzing properties of three-dimensional printing materials used to manufacture objects in the system;
identifying a purpose of usage of the object in the system;
identifying a clearance between the object and an adjacent object in a system; and
identifying a temperature variation in the object due to operational and environmental parameters associated with the system.

14. The computer program product of claim 13, wherein the altering the specification of the object is based on the analyzing the system and comprises one or more selected from a group consisting of:
changing the specification to include one or more of the one or more other materials at the portion;
changing the clearance between the object and an adjacent object in a system; and
identifying a level of cooling associated with the object.

15. A computer system comprising:
a processor set;
one or more computer-readable storage media; and
program instructions stored on the one or more computer-readable storage media to cause the processor set to perform operations comprising:
predicting thermal expansion in an object by analyzing a digital model of the object, wherein the digital model is based on a specification of the object in which the object is composed of a first three-dimensional printing material;
predicting stress in the object based on the predicted thermal expansion;
identifying a portion of the object based on the predicted thermal expansion exceeding a first predefined limit or the predicted stress exceeding a second predefined limit;
performing simulations using different digital models of the object that correspond to different designs of the object that include one or more other three-dimensional printing materials at the portion, wherein a respective one of the simulations for a respective one of the different designs predicts thermal expansion and stress associated with the respective one of the different designs; and
altering the specification of the object based on the simulations.

16. The computer system of claim 15, wherein:
the first three-dimensional printing material has a first coefficient of thermal expansion; and
respective ones of the one or more other three-dimensional printing materials are different than the first three-dimensional printing material and have respective coefficients of thermal expansion that are different than the first coefficient of thermal expansion.

17. The computer system of claim 16, wherein the operations further comprise obtaining the first coefficient of thermal expansion and the respective coefficients of thermal expansion from a material knowledge base.

18. The computer system of claim 15, wherein the operations further comprise obtaining parameters associated with the first three-dimensional printing material and the parameters associated with the one or more other three-dimensional printing materials from a material knowledge base.

19. The computer system of claim 15, wherein the operations further comprise analyzing a system that includes the object, wherein the analyzing includes one or more selected from a group consisting of:
analyzing properties of three-dimensional printing materials used to manufacture objects in the system;
identifying a purpose of usage of the object in the system;
identifying a clearance between the object and an adjacent object in a system; and
identifying a temperature variation in the object due to operational and environmental parameters associated with the system.

20. The computer system of claim 19, wherein the altering the specification of the object is based on the analyzing the system and comprises one or more selected from a group consisting of:
changing the specification to include one or more of the one or more other materials at the portion;
changing the clearance between the object and an adjacent object in a system; and
identifying a level of cooling associated with the object.
